(19) United States
(12) Patent Application Publication
(10) Pub. No.: US 2024/0141086 A1
(43) Pub. Date: May 2, 2024

(54) CURABLE COMPOSITION COMPRISING LIGHT POLYMERIZABLE LIQUID AND EPOXY PRECURSOR FOR COATING, 2D OBJECT FORMATION AND 3D PRINTING

(71) Applicant: BASF SE, Ludwigshafen am Rhein (DE)

(72) Inventors: Fan ZHANG, Shanghai (CN); Chong Xi WANG, Shanghai (CN); Zhi Zhong CAI, Shanghai (CN)

(21) Appl. No.: 18/278,445

(22) PCT Filed: Feb. 11, 2022
(86) PCT No.: PCT/EP2022/053422

§ 371 Date: Aug. 23, 2023

(30) Foreign Application Priority Data
Feb. 25, 2022 (WO) PCT/CN2021/077876

(51) Int. Cl. C08F 226/10; B29C 64/129; C08F 2/50; C08F 222/10; C08G 59/24; C08G 59/42; C08G 59/50; C08K 5/5397; C09D 11/101

(52) U.S. Cl. CPC C08F 226/10; B29C 64/129; C08F 2/50; C08F 222/102; C08F 222/1065; C08F 222/1067; C08G 59/245; C08G 59/42; C08G 59/5033; C08K 5/5397; C09D 11/101; B33Y 10/00

(57) ABSTRACT

This disclosure relates to a curable composition comprising (a) at least one light polymerizable liquid; (b) at least one epoxy precursor dissolved in component (a); and (c) at least one photoinitiator; wherein the curable composition exhibits no more than 15% increase in viscosity at 25° C. after 7 days at room temperature.

### TECHNOLOGY FIELD

The present invention relates to the technical field of chemical materials for creating objects with single layer or multiple layers, such as coating, two-dimensional (hereinafter referred to as “2D”) object formation, and three-dimensional (hereinafter referred to as “3D”) printing, and in particular relates to 1K epoxy dual cure composition, i.e., a curable composition comprising light polymerizable liquid and epoxy precursor for coating, 2D object formation, and 3D printing, to a process of forming objects with single layer or multiple layers by using the composition and to objects with single layer or multiple layers.

### BACKGROUND

Photopolymers are a class of polymeric materials that changes their properties when exposed to light, often in the ultraviolet or visible region of the electromagnetic spectrum. These changes are often manifested structurally, such as liquid resin hardening into solid as a result of cross-linking when exposed to light. This feature has given photopolymers wide applications in UV coating, UV inks for 2D object formation, and 3D printing.

UV coating is a surface treatment process which applies an outer layer to a structure to provide UV protection, extra moisture resistance and more durability.

2D object formation is a process to create a layer with designed shape on to a structure.

3D printing or additive manufacturing (AM) is a manufacturing method that seeks to avoid traditional manufacturing techniques that are either subtractive (i.e., machining and ablation) or formative (i.e., molding and casting), and in doing so leverages considerable benefits in terms of design freedom. UV curable photopolymer is a class of 3D printable materials which have been widely used in various applications including prototyping of plastic parts, metal investment casting, dental applications, etc. Up to date, the UV curable photopolymers on the market are suitable in making prototypes and demonstrations but may not be adequate for real applications that require thermal and mechanical properties. To bridge the gap from prototyping to real manufacturing, it is critical to have advanced materials with specific properties dictated by targeted industrial applications.

Automotive industry is the third most important consuming sector of polymers. The growing demand on fuel efficiency and light weighting has made 3D printing a promising technique to manufacture plastic components within a vehicle, such as interior parts, connectors and functional prototypes. These applications usually require the material to possess adequate thermal deflection temperature (HDT) and mechanical performances, which can hardly be achieved by traditional acrylate-based photopolymers. Therefore, it becomes crucial to employ new chemistry/process in 3D material development for advanced performances that could match existing plastics fabricated with traditional manufacturing methods.

To solve this issue, attempts have been made to combine epoxy precursors with a light polymerizable liquid. However, epoxy precursors, such as mixtures of epoxy/amine and epoxy/hydroxyl, usually reacts rapidly upon mixing, making it not possible to be used as a 1 K epoxy resin composition which requires no pre-mixing process. Therefore, there is a strong need to provide a 1K epoxy dual cure composition with good storage stability, which enables the development of an object with single or multiple layers with high HDT and high toughness.

### SUMMARY OF THE INVENTION

It is an object of the invention to provide a curable composition with good storage stability, which enables the development of an object with single or multiple layers with high HDT and high toughness, wherein the curable composition comprises (a) at least one light polymerizable liquid; (b) at least one epoxy precursor dissolved in component (a); and (c) at least one photoinitiator; and wherein the curable composition exhibits no more than 15% increase in viscosity at 25° C. after 7 days at room temperature.

Another object of the present invention is to provide an object with single or multiple layers formed from the curable composition of the present invention.

A further object of the present invention is to provide a process of forming object with single or multiple layers by using the curable composition of the present invention.

It has been surprisingly found that the above objects can be achieved by following embodiments:
1. A curable composition comprising
(a) at least one light polymerizable liquid;
(b) at least one epoxy precursor dissolved in component (a); and
(c) at least one photoinitiator;
wherein the curable composition exhibits no more than 15% increase in viscosity at 25° C. after 7 days at room temperature.
2. The curable composition according to item 1, wherein the curable composition exhibits no more than 10%, preferably no more than 5% increase in viscosity at 25° C. after 7 days at room temperature.
3. The curable composition according to items 1 or 2, wherein component (a) comprises at least one mono-functional reactive diluent (a1) having a nitrogen atom carrying an ethylenically unsaturated functional group.
4. The curable composition according to item 3, wherein the reactive diluent (a1) is a N-vinyl heterocyclic compound, preferably one ring carbon atom in the N-vinyl heterocyclic compound carries an oxo group, more preferably the ring carbon atom carrying the oxo group together with the nitrogen atom of the N-vinyl moiety forms a lactam structure.
5. The curable composition according to item 4, wherein the heterocyclic ring of the N-vinyl heterocyclic compound is a 5- to 8-membered ring containing 0 to 3 (preferably 1 or 2) heteroatoms selected from N, O and S in addition to the nitrogen atom in the N-vinyl moiety.
6. The curable composition according to any of items 3 to 5, wherein the reactive diluent (a1) is selected from the group consisting of N-vinylpyrrolidone, N-vinyl caprolactam and N-vinyl oxazolidinone of formula (A):

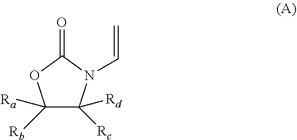

wherein Rₐ, R_{b}, R_{c} and R_{d} are independently of each other a hydrogen atom or an organic group having not more than 10 carbon atoms, preferably no more than 6 carbon atoms, such as a C₁-C₆ alkyl group, or a C₁-C₆ alkoxy group.
7. The curable composition according to any of items 3 to 6, wherein the amount of the reactive diluent (a1) is in the range from 10 to 50 wt. %, preferably from 15 to 50 wt. %, more preferably from 20 to 45 wt. %, based on the total weight of the curable composition.
8. The curable composition according to any of items 3 to 7, wherein component (a) further comprises at least one photopolymerizable compound (a2) containing at least one ethylenically unsaturated functional group, preferably photopolymerizable compound (a2) is based on (meth)acrylate.
9. The curable composition according to any of items 1 to 8, wherein the amount of component (a) is in the range from 20 to 94 wt. %, preferably from 30 to 92 wt. %, more preferably from 40 to 90 wt. % or from 40 to 75 wt. %, based on the total weight of the curable composition.
10. The curable composition according to any of items 1 to 9, wherein the epoxy precursor as component (b) comprises reactive end groups selected from the group consisting of epoxy/amine, epoxy/hydroxyl, and mixtures thereof.
11. The curable composition according to any of items 1 to 10, wherein the epoxy precursor as component (b) comprises at least one epoxy compound (b1) and at least one latent epoxy crosslinker (b2).
12. The curable composition according to item 11, wherein the melting point of the latent epoxy crosslinker (b2) is in the range from 100 to 250° C., preferably from 130 to 220° C., more preferably from 150 to 190° C.
13. The curable composition according to item 11 or 12, wherein the latent epoxy crosslinker is diamino diphenyl sulfone and/or derivative thereof.
14. The curable composition according to any of items 11 to 13, wherein the latent epoxy cross-linker is selected from the group consisting of the compound of formula (I), compound of formula (II) and compound of formula (III):

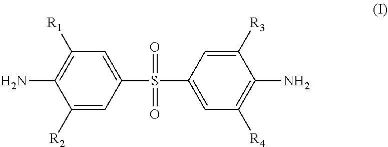

wherein R₁, R₂, R₃ and R₄ are each independently H or C₁-C₆ alkyl;

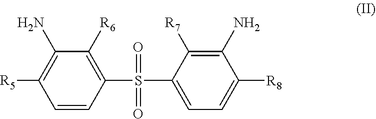

wherein R₅, R₆, R₇ and R₈ are each independently H or C₁-C₆ alkyl;

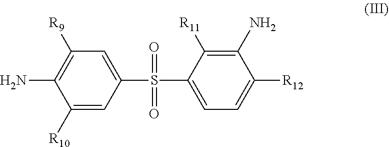

wherein R₉, R₁₀, R₁₁ and R₁₂ are each independently H or C₁-C₆ alkyl.
15. The curable composition according to any of items 1 to 14, wherein weight ratio of component (a) to component (b) is in the range from 1:5 to 20:1, preferably from 1:2 to 10:1.
16. A process of forming single layer coating or 2D object, comprising
(i) apply a layer of the composition onto the surface of a structure;
(ii) applying light to cure the curable composition according to any of item 1 to 15 to form an intermediate coating or 2D object;
(iii) treating the cured coating or 2D object as a whole by heating and/or microwave irradiating to form a final coating or 2D object.
17. A process of forming 3D object, comprising
(i) applying light to cure the curable composition according to any of item 1 to 15 layer by layer to form an intermediate 3D object;
(ii) further applying light to cure the intermediate 3D object as a whole to form a cured 3D object; and
(iii) treating the cured 3D object as a whole by heating and/or microwave irradiating to form a final 3D object.
18. A single layer coating or 2D object or 3D object formed from the curable composition according to any of items 1 to 15.
19. The 3D object according to item 18, wherein the 3D object includes plumbing fixtures, household, toy, jig, mould and interior part and connector within a vehicle.

The curable composition according to the present invention is a 1K epoxy dual cure composition comprising both light polymerizable liquid and epoxy precursor, shows excellent storage stability and excellent printing accuracy, which enables the development of objects with single layer or multiple layers with high HDT and high toughness.

### DESCRIPTION OF THE DRAWING

FIG. 1(a) shows the picture of standard benchmark model and FIG. 1(b) shows the picture of 3D-printed object obtained by printing the composition of example 4 according to the standard benchmark model.

FIG. 2 shows the pictures of 3D-printed objects obtained by printing the composition of example 4.

FIG. 3 shows the normalized viscosities of compositions of example 5 and comparative examples 2, 3 and 4 at different days.

### EMBODIMENT OF THE INVENTION

The undefined article “a”, “an”, “the” means one or more of the species designated by the term following said article.

In the context of the present disclosure, any specific values mentioned for a feature (comprising the specific values mentioned in a range as the end point) can be recombined to form a new range.

In the context of the present disclosure, coating refers to a process of coating the composition evenly on clean slide and expose it under UV source; 2D object formation refers to a process of forming a 2D pattern by using the composition; and 3D printing refers to a process of forming a 3D-printed object by using the composition.

### Curable Composition

One aspect of the present invention is directed to a curable composition comprising
(a) at least one light polymerizable liquid;
(b) at least one epoxy precursor dissolved in component (a); and
(c) at least one photoinitiator;
wherein the curable composition exhibits no more than 15% increase in viscosity at 25° C. after 7 days at room temperature.

The curable composition of the present invention is a liquid composition. The term “liquid composition” means the composition flows under its own weight.

The curable composition of the present invention is a 1K epoxy dual cure composition. The curable composition of the present invention shows excellent storage stability.

According to the present invention, the curable composition exhibits no more than 15% increase in viscosity at 25° C. after 7 days at room temperature, for example no more than 14%, no more than 13%, no more than 12%, no more than 11%; preferably no more than 10%, for example no more than 9%, no more than 8%, no more than 7%, no more than 6%; more preferably no more than 5%, no more than 4%, no more than 3%, or no more than 2% increase in viscosity at 25° C. after 7 days at room temperature.

In a preferred embodiment, the curable composition exhibits no more than 25% increase in viscosity at 25° C. after 14 days at room temperature, for example no more than 20%, no more than 18%, no more than 15%, no more than 12%; preferably no more than 10%, for example no more than 9%, no more than 8%, no more than 7%, no more than 6%; more preferably no more than 5%, no more than 4%, no more than 3%, or no more than 2% increase in viscosity at 25° C. after 14 days at room temperature.

Room temperature refers generally to a temperature of 25±2° C.

Viscosity (such as the viscosity of the curable composition) can be measured by using a Brookfield AMETEK DV3T rheometer. For each test, approximately 0.65 ml of sample was used, and a shear rate between 1 s⁻¹ and 30 s⁻¹ was selected according to the viscosity.

The viscosity of the curable composition of the present invention depends on the specific printing process. Usually, the curable composition of the present invention has a viscosity at 25° C. of no more than 1500 mPa·s, preferably no more than 1300 mPa·s, more preferably no more than 1200 mPa·s, in particular no more than 1100 mPa·s.

As used in this disclosure, expression “(b) at least one epoxy precursor dissolved in component (a)” or “component (b) dissolved in component (a)” or similar expression means component (b) and component (a) can form a liquid mixture without solid particles.

### Component (a)

The curable composition of the present invention comprises at least one light polymerizable liquid as component (a).

According to a preferred embodiment of the invention, the functionality of the light polymerizable liquid can be in the range from 1 to 12, for example 1.2, 1.5, 1.8, 2, 2.2. 2.5, 3, 3.5,4, 5, 6, 7, 8, 9, 10, 11, preferably 1 to 8, or 1.5 to 6, or 1.5 to 4.

According to the present invention, component (a) can comprise at least one mono-functional reactive diluent (a1) having a nitrogen atom carrying an ethylenically unsaturated functional group. A person skilled in the art could understand that the ethylenically unsaturated functional group in the context of the present disclosure is a light-curable group.

The reactive diluent (a1) can be a N-vinyl heterocyclic compound, preferably one ring carbon atom in the N-vinyl heterocyclic compound carries an oxo group, more preferably the ring carbon atom carrying the oxo group together with the nitrogen atom of the N-vinyl moiety forms a lactam structure.

In a preferred embodiment, the heterocyclic ring of the N-vinyl heterocyclic compound is a 5- to 8-membered ring containing 0 to 3 (preferably 1 or 2) heteroatoms selected from N, O and S in addition to the nitrogen atom in the N-vinyl moiety. For example, the heterocyclic ring of the N-vinyl heterocyclic compound can be a 5- or 6-membered ring. The heterocyclic ring can contain no further heteroatom in addition to the nitrogen atom in the N-vinyl moiety. In a preferred embodiment, the heterocyclic ring can further contain 0 to 3, preferably 1 or 2 heteroatoms selected from N, O and S, preferably O in addition to the nitrogen atom in the N-vinyl moiety.

In a preferred embodiment, the reactive diluent (a1) can be selected from the group consisting of N-vinylpyrrolidone, N-vinyl caprolactam and N-vinyl oxazolidinone of formula (A):

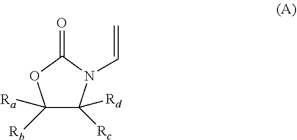

wherein Rₐ, R_{b}, R_{c} and R_{d} are independently of each other a hydrogen atom or an organic group having not more than 10 carbon atoms.

Preferably at least two of Rₐ to R_{d} in formula (A) are a hydrogen atom.

In a particularly preferred embodiment at least two of Rₐ to R_{d} in formula (A) are a hydrogen atom and any remaining Rₐ to R_{d} are an organic group having not more than 10 carbon atoms.

Preferably the organic group has not more than 6 carbon atoms, more preferably no more than 4 carbon atoms. In a particularly preferred embodiment, the organic group is an alkyl, or alkoxy group. In a preferred embodiment the organic group is a C₁-C₆ alkyl group, or a C₁-C₆ alkoxy group, more preferably a C₁-C₄ alkyl group, or a C₁-C₄ alkoxy group. In a most preferred embodiment, the organic group is a methyl group.

As examples of N-vinyloxazolidinone of formula (A) compounds may be mentioned, wherein Rₐ, R_{b}, R_{c} and R_{d} are a hydrogen atom (N-vinyloxazolidinone (VOX), or
Rₐ is a C₁-C₄ alkyl group, in particular a methyl group, and R_{b}, R_{c} and R_{d} are a hydrogen atom (N-vinyl-5-methyl oxazolidinone (VMOX)), or
Rₐ and R_{b} are a hydrogen atom and R_{c} and R_{d} are a C₁-C₄ alkyl group, in particular a methyl group.

Particularly preferred are VOX and VMOX, most preferred is VMOX.

The amount of the reactive diluent (a1) can be in the range from 10 to 50 wt. %, for example 15 wt. %, 20 wt. %, 25 wt. %, 30 wt. %, 35 wt. %, 40 wt. % or 45 wt. %, preferably from 15 to 50 wt. % or from 10 to 40 wt. %, more preferably from 20 to 45 wt. % or from 15 to 30 wt. %, based on the total weight of the curable composition.

According to the present invention, component (a) further comprises at least one photopolymerizable compound (a2) containing at least one ethylenically unsaturated functional group. The functionality of the photopolymerizable compound (a2) can be in the range from 1.2 to 12, for example 1.5, 1.8, 2, 2.2. 2.5, 3, 3.5,4, 5, 6, 7, 8, 9, 10, 11, preferably from 1.5 to 8, or from 1.5 to 6, or from 1.5 to 4.

In an embodiment of the invention, the ethylenically unsaturated functional group comprises a carbon-carbon unsaturated bond, such as those found in the following functional groups: allyl, vinyl, acrylate, methacrylate, acryloxy, methacryloxy, acrylamido, methacrylamido, acetylenyl, maleimido, and the like; preferably, the ethylenically unsaturated functional group comprises a carbon-carbon unsaturated double bond.

In a preferred embodiment, the ethylenically unsaturated functional group comprises (meth)acrylate. Preferably, component (a2) is based on (meth)acrylate.

In a preferred embodiment of the invention, the photopolymerizable compound (a2) comprises, in addition to the ethylenically unsaturated functional group, urethane group, ether group, ester group, carbonate group and any combination thereof.

Suitable photopolymerizable compound (a2) includes, for example, oligomer containing a core structure linked to the ethylenically unsaturated functional group, optionally via a linking group. The linking group can be an ether, ester, amide, urethane, carbonate, or carbonate group. In some instances, the linking group is part of the ethylenically unsaturated functional group, for instance an acryloxy or acrylamido group. The core group can be an alkyl (straight and branched chain alkyl groups), aryl (e.g. phenyl), polyether, polyester, siloxane, urethane, or other core structures and oligomers thereof. Suitable ethylenically unsaturated functional group may comprise carbon-carbon double bond such as methacrylate, acrylate, vinyl ether, allyl ether, acrylamide, methacrylamide, or a combination thereof. In some embodiments, suitable photopolymerizable compound (a2) comprise mono- and/or polyfunctional acrylate, such as mono (meth)acrylate, di(meth)acrylate, tri(meth)acrylate, or higher, or combination thereof. Optionally, the photopolymerizable compound (a2) may include a siloxane backbone in order to further improve cure, flexibility and/or additional properties of the radiation-curable composition for creation of objects with single or multiple layers.

In some embodiments, the oligomer as the photopolymerizable compound (a2) containing at least one ethylenically unsaturated functional group can be selected from the following classes: urethane (i.e. an urethane-based oligomer containing ethylenically unsaturated functional group), polyether (i.e. an polyether-based oligomer containing ethylenically unsaturated functional group), polyester (i.e. an polyester-based oligomer containing ethylenically unsaturated functional group), polycarbonate (i.e. an polycarbonate-based oligomer containing ethylenically unsaturated functional group), polyestercarbonate (i.e. an polyestercarbonate-based oligomer containing ethylenically unsaturated functional group), epoxy (i.e. an epoxy-based oligomer containing ethylenically unsaturated functional group), silicone (i.e. a silicone-based oligomer containing ethylenically unsaturated functional group) or any combination thereof. Preferably, the reactive oligomer containing at least one ethylenically unsaturated functional group can be selected from the following classes: a urethane-based oligomer, an epoxy-based oligomer, a polyester-based oligomer, a polyether-based oligomer, polyether urethane-based oligomer, polyester urethane-based oligomer or a silicone-based oligomer, as well as any combination thereof.

In a preferred embodiment of the invention, photopolymerizable compound (a2) containing at least one ethylenically unsaturated functional group comprises a urethane-based oligomer comprising urethane repeating units and one, two or more ethylenically unsaturated functional groups, for example carbon-carbon unsaturated double bond such as (meth)acrylate, (meth)acrylamide, allyl and vinyl groups. Preferably, the photopolymerizable compound (a2) contains at least one urethane linkage (for example, one, two or more urethane linkages) within the backbone of the oligomer molecule and at least one acrylate and/or methacrylate functional groups (for example, one, two or more acrylate and/or methacrylate functional groups) pendent to the oligomer molecule. In some embodiments, aliphatic, cycloaliphatic, or mixed aliphatic and cycloaliphatic urethane repeating units are suitable. Urethanes are typically prepared by the condensation of a diisocyanate with a diol. Aliphatic urethanes having at least two urethane moieties per repeating unit are useful. In addition, the diisocyanate and diol used to prepare the urethane comprise divalent aliphatic groups that may be the same or different.

In one embodiment, photopolymerizable compound (a2) containing at least one ethylenically unsaturated functional group comprises polyester urethane-based oligomer or polyether urethane-based oligomer containing at least one ethylenically unsaturated functional group. The ethylenically unsaturated functional group can be carbon-carbon unsaturated double bond, such as acrylate, methacrylate, vinyl, allyl, acrylamide, methacrylamide, etc., preferably acrylate and methacrylate. The functionality of these polyester or polyether urethane-based oligomer is 1 or greater, specifically about 2 ethylenically unsaturated functional group per oligomer molecule.

Suitable urethane-based oligomers are known in the art and may be readily synthesized by a number of different procedures. For example, a polyfunctional alcohol may be reacted with a polyisocyanate (preferably, a stoichiometric excess of polyisocyanate) to form an NCO-terminated pre-oligomer, which is thereafter reacted with a hydroxy-functional ethylenically unsaturated monomer, such as hydroxy-functional (meth)acrylate. The polyfunctional alcohol may be any compound containing two or more OH groups per molecule and may be a monomeric polyol (e.g., a glycol), a polyester polyol, a polyether polyol or the like. The urethane-based oligomer in one embodiment of the invention is an aliphatic urethane-based oligomer containing (meth)acrylate functional group.

Suitable polyether or polyester urethane-based oligomers include the reaction product of an aliphatic or aromatic polyether or polyester polyol with an aliphatic or aromatic polyisocyanate that is functionalized with a monomer containing the ethylenically unsaturated functional group, such as (meth)acrylate group. In a preferred embodiment, the polyether and polyester are aliphatic polyether and polyester, respectively. In a preferred embodiment, the polyether and polyester urethane-based oligomers are aliphatic polyether and polyester urethane-based oligomers and comprise (meth)acrylate group.

Epoxy-based oligomer containing at least one ethylenically unsaturated functional group can be epoxy-based (meth)acrylate oligomer. The epoxy-based (meth)acrylate oligomer is obtainable by reacting epoxides with (meth)acrylic acid.

Examples of suitable epoxides include epoxidized olefins, aromatic glycidyl ethers or aliphatic glycidyl ethers, preferably those of aromatic or aliphatic glycidyl ethers.

Examples of possible epoxidized olefins include ethylene oxide, propylene oxide, isobutylene oxide, 1-butene oxide, 2-butene oxide, vinyloxirane, styrene oxide or epichlorohydrin, preference being given to ethylene oxide, propylene oxide, isobutylene oxide, vinyloxirane, styrene oxide or epichlorohydrin, particular preference to ethylene oxide, propylene oxide or epichlorohydrin, and very particular preference to ethylene oxide and epichlorohydrin.

Aromatic glycidyl ethers are, for example, bisphenol A diglycidyl ether, bisphenol F diglycidyl ether, bisphenol B diglycidyl ether, bisphenol S diglycidyl ether, hydroquinone diglycidyl ether, alkylation products of phenol/dicyclopentadiene, e.g., 2,5-bis[(2,3-epoxypropoxy)phenyl]octahydro-4,7-methano-5H-indene (CAS No. [13446-85-0]), tris[4-(2,3-epoxypropoxy)phenyl]methane isomers (CAS No. [66072-39-7]), phenol-based epoxy novolaks (CAS No. [9003-35-4]), and cresol-based epoxy novolaks (CAS No. [37382-79-9]).

Examples of aliphatic glycidyl ethers include 1,4-butanediol diglycidyl ether, 1,6-hexanediol diglycidyl ether, trimethylolpropane triglycidyl ether, pentaerythritol tetraglycidyl ether, 1,1,2,2-tetrakis[4-(2,3-epoxypropoxy)phenyl]ethane (CAS No. [27043-37-4]), diglycidyl ether of polypropylene glycol (α,ω-bis(2,3-epoxypropoxy)poly(oxypropylene), CAS No. [16096-30-3]) and hydrogenated bisphenol A (2,2-bis[4-(2,3-epoxypropoxy)cyclohexyl]propane, CAS No. [13410-58-7]).

In a preferred embodiment, the epoxy-based (meth)acrylate oligomer is an aromatic glycidyl (meth)acrylate.

The polycarbonate-based oligomer containing at least one ethylenically unsaturated functional group can comprise polycarbonate-based (meth)acrylates oligomer, which is obtainable in a simple manner by trans-esterifying carbonic esters with polyhydric, preferably dihydric, alcohols (diols, hexanediol for example) and subsequently esterifying the free OH groups with (meth)acrylic acid, or else by transesterification with (meth)acrylic esters, as described for example in EP-A 92 269. They are also obtainable by reacting phosgene, urea derivatives with polyhydric, e.g., dihydric, alcohols.

Also conceivable are (meth)acrylates of polycarbonate polyols, such as the reaction product of one of the aforementioned diols or polyols and a carbonic ester and also a hydroxyl-containing (meth)acrylate.

Examples of suitable carbonic esters include ethylene carbonate, 1,2- or 1,3-propylene carbonate, dimethyl carbonate, diethyl carbonate or dibutyl carbonate.

Examples of suitable hydroxyl-containing (meth)acrylates are 2-hydroxyethyl (meth)acrylate, 2- or 3-hydroxypropyl (meth)acrylate, 1,4-butanediol mono(meth)acrylate, neopentyl glycol mono(meth)acrylate, glyceryl mono- and di(meth)acrylate, trimethylolpropane mono- and di(meth)acrylate, and pentaerythritol mono-, di-, and tri(meth)acrylate.

As the photopolymerizable compound (a2), epoxy-based oligomer containing at least one ethylenically unsaturated functional group, especially epoxy-based (meth)acrylate oligomer is particularly preferred.

The oligomer as the photopolymerizable compound (a2) preferably has a number-average molar weight Mn of 200 to 20 000, more preferably of 200 to 10 000 g/mol, and very preferably of 250 to 3000 g/mol.

In one embodiment, the oligomer as the photopolymerizable compound (a2) has a glass transition temperature in the range from 0 to 200° C., for example 5° C., 10° C., 20° C., 30° C., 40° C., 50° C., 80° C., 100° C., 120° C., 150° C, 180° C. or 190° C., preferably from 10 to 180° C., more preferably from 30 to 150° C.

As an alternative for or in addition to the oligomer, the photopolymerizable compound (a2) can also comprise at least one monomer different from reactive diluent (a1), which can be selected from the group consisting of (meth)acrylate monomer, (meth)acrylamide monomer, vinylaromatics having up to 20 carbon atoms, vinyl esters of carboxylic acids having up to 20 carbon atoms, α,β-unsaturated carboxylic acids having 3 to 8 carbon atoms and their anhydrides, and vinyl substituted heterocycles,

The (meth)acrylate monomer can be monofunctional or multifunctional (such as difunctional, trifunctional) (meth)acrylate monomer. Exemplary (meth)acrylate monomer can include C₁ to C₂₀ alkyl (meth)acrylate, C₁ to C₁₀ hydroxyalkyl (meth)acrylate, C₃ to C₁₀ cycloalkyl (meth)acrylate, urethane acrylate, 2-(2-ethoxy)ethyl acrylate, tetrahydrofurfuryl (meth)acrylate, 2-phenoxyethylacrylate, dicyclopentenyloxyethyl (meth)acrylate, dicyclopentadienyl (meth)acrylate, caprolactone (meth)acrylate, morpholine (meth)acrylate, ethoxylated nonyl phenol (meth)acrylate, (5-ethyl-1,3-dioxan-5-yl) methyl acrylate, phenyl (meth)acrylate, benzyl (meth)acrylate, phenethyl (meth)acrylate, dicyclopentanyl (meth)acrylate, 3,3,5-trimethylcyclohexyl (meth)acrylate and dicyclopentenyl (meth)acrylate.

Specific examples of C₁ to C₂₀ alkyl (meth)acrylate can include methyl (meth)acrylate, ethyl (meth)acrylate, isopropyl (meth)acrylate, n-propyl (meth)acrylate, n-butyl (meth)acrylate, isobutyl (meth)acrylate, tert-butyl (meth)acrylate, sec-butyl (meth)acrylate, pentyl (meth)acrylate, n-hexyl (meth)acrylate, octyl (meth)acrylate, isooctyl (meth)acrylate, 2-ethylhexyl (meth)acrylate, decyl (meth)acrylate, isodecyl (meth)methacrylate, n-lauryl (meth)acrylate, n-tridecyl (meth)acrylate, n-cetyl (meth)acrylate, n-stearyl (meth)acrylate, isomyristyl (meth)acrylate, stearyl (meth)acrylate, and isostearyl (meth)acrylate (ISTA). C₆ to C₁₈ alkyl (meth)acrylate, especially C₆ to C₁₆ alkyl (meth)acrylate or C₈ to C₁₂ alkyl (meth)acrylate is preferred.

Specific examples of C₁ to C₁₀ hydroxyalkyl (meth)acrylate, such as C₂ to C₈ hydroxyalkyl (meth)acrylate can include 2-hydroxyethyl (meth)acrylate, 2-hydroxypropyl (meth)acrylate, 3-hydroxypropyl (meth)acrylate, 3-hydroxybutyl (meth)acrylate, 4-hydroxybutyl (meth)acrylate, 6-hydroxyhexyl (meth)acrylate, or 3-hydroxy-2-ethylhexyl (meth)acrylate etc.

Specific examples of C₃ to C₁₀ cycloalkyl (meth)acrylate can include isobornyl acrylate, isobornyl methacrylate, cyclohexyl acrylate, cyclohexyl methacrylate, tricyclodecane dimethanol diacrylate and tricyclodecane dimethanol dimethacrylate.

Examples of the multifunctional (meth)acrylate monomer can include (meth)acrylic esters and especially acrylic esters of polyfunctional alcohols, particularly those which other than the hydroxyl groups comprise no further functional groups or, if they comprise any at all, comprise ether groups. Examples of such alcohols are, e.g., difunctional alcohols, such as ethylene glycol, propylene glycol, and their counterparts with higher degrees of condensation, for example such as diethylene glycol, triethylene glycol, dipropylene glycol, tripropylene glycol etc., 1,2-, 1,3- or 1,4-butanediol, 1,5-pentanediol, 1,6-hexanediol, 3-methyl-1,5-pentanediol, neopentyl glycol, alkoxylated phenolic compounds, such as ethoxylated and/or propoxylated bisphenols, 1,2-, 1,3- or 1,4-cyclohexanedimethanol, alcohols with a functionality of three or higher, such as glycerol, trimethylolpropane, butanetriol, trimethylolethane, pentaerythritol, ditrimethylolpropane, dipentaerythritol, sorbitol, mannitol, and the corresponding alkoxylated, especially ethoxylated and/or propoxylated, alcohols.

In the context of the present disclosure, term “(meth)acrylamide monomer” means a monomer comprises a (meth)acrylamide moiety. The structure of the (meth)acrylamide moiety is as follows: CH₂═CR¹—CO—N, wherein R¹ is hydrogen or methyl. Specific example of (meth)acrylamide monomer can include acryloylmorpholine, methacryloylmorpholine, N-(hydroxymethyl)acrylamide, N-hydroxyethyl acrylamide, N-isopropylacrylamide, N-isopropylmethacrylamide, N-tert-butylacrylamide, N,N′-methylenebisacrylamide, N-(isobutoxymethyl)acrylamide, N-(butoxymethyl)acrylamide, N-[3-(dimethylamino)propyl]methacrylamide, N,N-dimethylacrylamide, N,N-diethylacrylamide, N-(hydroxymethyl)methacrylamide, N-hydroxyethyl methacrylamide, N-isopropylmethacrylamide, N-isopropylmethmethacrylamide, N-tert-butylmethacrylamide, N,N′-methylenebismethacrylamide, N-(isobutoxymethyl)methacrylamide, N-(butoxymethyl)methacrylamide, N-[3-(dimethylamino)propyl]methmethacrylamide, N,N-dimethylmethacrylamide and N,N-diethylmethacrylamide. The (meth)acrylamide monomer can be used alone or in combination.

Examples of vinylaromatics having up to 20 carbon atoms can include, such as styrene and C₁-C₄-alkyl substituted styrene, such as vinyltoluene, p-tert-butylstyrene and α-methyl styrene.

Examples of vinyl esters of carboxylic acids having up to 20 carbon atoms (for example 2 to 20 or 8 to 18 carbon atoms) can include vinyl laurate, vinyl stearate, vinyl propionate, and vinyl acetate.

Example of α,β-unsaturated carboxylic acids having 3 to 8 carbon atoms can be acrylic acid.

Preferred monomers are (meth)acrylate monomer.

In one embodiment, the viscosity of the photopolymerizable compound (a2) at 60° C. can be in the range from 10 to 100000 cP, for example 20 cP, 50 cP, 100 cP, 200 cP, 500 cP, 800 cP, 1000 cP, 2000 cP, 3000 cP, 4000 cP, 5000 cP, 6000 cP, 7000 cP, 8000 cP, 10000 cP, 20000 cP, 30000 cP, 40000 cP, 50000 cP, 60000 cP, 70000 cP, 80000 cP, 90000 cP, 95000 cP, preferably from 20 to 60000 cP, for example from 100 to 15000 cP, or from 500 to 60000 cP.

The amount of component (a) can be in the range from 20 to 94 wt. %, for example 25 wt. %, 30 wt. %, 40 wt. %, 50 wt. %, 60 wt. %, 70 wt. %, 80 wt. %, 90 wt. %, 92 wt. %, preferably from 30 to 92 wt. %, more preferably from 40 to 90 wt. % or from 40 to 75 wt. %, or from 40 to 65 wt. %, based on the total weight of the curable composition.

### Epoxy Precursor (b)

The curable composition of the present invention comprises at least one epoxy precursor as component (b). According to the present invention, said component (b) is dissolved in component (a).

In the context of the present disclosure, epoxy precursor means the precursor can be further reacted to form the epoxy resin (cured epoxy resin).

In an embodiment, the epoxy precursor as component (b) comprises reactive end groups selected from the group consisting of epoxy/amine, epoxy/hydroxyl, and mixtures thereof.

In a preferred embodiment, the epoxy precursor as component (b) comprises at least one epoxy compound (b1) and at least one latent epoxy crosslinker (b2).

The epoxy compound generally has on average more than one epoxide group per molecule, which is converted by reaction with suitable curing agents (crosslinker) into, or cured epoxy resin.

The epoxy compound (b1) usually has from 2 to 10, preferably from 2 to 6, very particularly preferably from 2 to 4, and in particular 2, epoxy groups per molecule. The epoxy groups in particular involve the glycidyl ether groups produced during the reaction of alcohol groups with epichlorohydrin. The epoxy compound can involve low-molecular-weight compounds which generally have an average molar mass (Mn) smaller than 1000 g/mol, or higher-molecular-weight compounds (polymers). Epoxy compounds (b1) preferably have a degree of oligomerization of from 2 to 25, particularly preferably from 2 to 10 units. They can involve (cyclo)aliphatic compounds, or compounds having aromatic groups. In particular, the epoxy compounds involve compounds having two aromatic or aliphatic 6-membered rings, or oligomers of these. Industrially important materials are epoxy compounds obtainable via reaction of epichlorohydrin with compounds having at least two reactive H atoms, in particular with polyols. Particularly important materials are epoxy compounds obtainable via reaction of epichlorohydrin with compounds comprising at least two, preferably two, hydroxy groups, and comprising two aromatic or aliphatic 6-membered rings. Examples that may be mentioned of these epoxy compounds (b1) of the invention are in particular bisphenol A and bisphenol F, and also hydrogenated bisphenol A and bisphenol F—the corresponding epoxy compounds being the diglycidyl ethers of bisphenol A or bisphenol F, or of hydrogenated bisphenol A or bisphenol F. It is usual to use bisphenol A diglycidyl ether (DGEBA) as epoxy compound (b1) in this invention. In the invention, the expressions bisphenol A diglycidyl ether (DEGBA) and bisphenol F diglycidyl ether (DGEBF) mean not only the corresponding monomers but also the corresponding oligomer. The epoxy compound (b1) of the invention is preferably a diglycidyl ether of monomeric or oligomeric diol. The diol here is preferably one selected from the group consisting of bisphenol A or bisphenol F, or of hydrogenated bisphenol A or bisphenol F, and the degree of oligomerization of the oligomeric diol is preferably from 2 to 25, particularly preferably from 2 to 10, units.

Other suitable epoxy compounds (b1) of this invention are tetraglycidylmethylenedianiline (TGMDA) and triglycidylaminophenol, and mixtures thereof. It is also possible to use reaction products of epichlorohydrin with other phenols, e.g. with cresols or with phenol-aldehyde adducts, such as phenol-formaldehyde resins, in particular novolaks. Epoxy compounds which do not derive from epichlorohydrin are also suitable. Examples of those that can be used are epoxy compounds which comprise epoxy groups via reaction with glycidyl (meth)acrylate.

According to the present invention, it is preferable that epoxy compounds (b1) or mixtures thereof used are liquid at room temperature, in particular with a viscosity in the range from 8000 to 12 000 Pa·s. The epoxy equivalent weight (EEW) gives the average mass of the epoxy compound in g per mole of epoxy group. It is preferable that the epoxy compound (b1) of the invention have an EEW in the range from 150 to 250, in particular from 170 to 200.

The amount of epoxy compound (b1) can be in the range from 5 to 50 wt. %, for example 10 wt. %, 15 wt. %, 20 wt. %, 25 wt. %, 30 wt. %, 35 wt. %, 40 wt. %, or 45 wt. %, preferably from 10 to 50 wt. %, from 15 to 50 wt. %, from 20 to 50 wt. %, from 25 to 50 wt. %, from 30 to 50 wt. %, or from 5 to 45 wt. %, from 10 to 45 wt. %, from 15 to 45 wt. %, from 20 to 45 wt. %, from 25 to 45 wt. %, or from 30 to 45 wt. %, based on the total weight of the curable composition.

According to the present invention, the epoxy precursor as component (b) can comprise at least one latent epoxy crosslinker (b2) in addition to the at least one epoxy compound (b1).

In a preferred embodiment, the melting point of the latent epoxy crosslinker (b2) can be in the range from 100 to 250° C., for example 110° C., 120° C., 130° C., 140° C., 150° C., 160° C., 170° C., 180° C., 190° C., 200° C., 220° C. or 240° C., preferably from 130 to 220° C., 130 to 195° C. or 140 to 195° C., more preferably from 150 to 190° C. or 160 to 185° C.

According to a preferred embodiment, the latent epoxy crosslinker (b2) can be diamino diphenyl sulfone and/or derivative thereof.

The latent epoxy crosslinker can be selected from the group consisting of the compound of formula (I), compound of formula (II) and compound of formula (III):

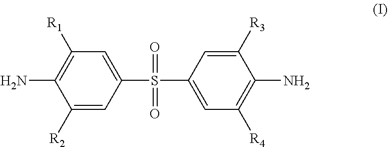

wherein R₁, R₂, R₃ and R₄ are each independently H or C₁-C₆ alkyl;

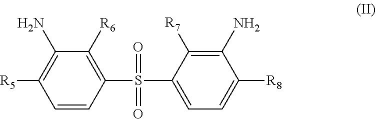

wherein R₅, R₆, R₇ and R₈ are each independently H or C₁-C₆ alkyl;

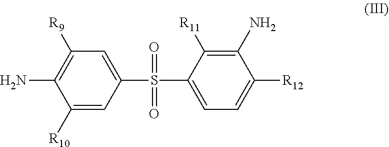

wherein R₉, R₁₀, R₁₁ and R₁₂ are each independently H or C₁-C₆ alkyl.

Preferably, R₁, R₂, R₃ and R₄ in formula (I) are each independently H or C₁-C₄ alkyl, more preferably H, methyl or ethyl, in particular H.

Preferably, R₅, R₆, R₇ and R₈ in formula (II) are each independently H or C₁-C₄ alkyl, more preferably H, methyl or ethyl, in particular H.

Preferably, R₉, R₁₀, R₁₁ and R₁₂ in formula (III) are each independently H or C₁-C₄ alkyl, more preferably H, methyl or ethyl, in particular H.

In a preferred embodiment, the latent crosslinker (b2) is soluble in the reactive diluent (a1). The solubility of the latent crosslinker (b2) in the reactive diluent (a1) can be more than 1 g/100 mL, more than 5 g/100 mL, more than 10 g/100 mL, more than 20 g/100 mL, for example more than 30 g/100 mL, or more than 40 g/100 mL, or more than 50 g/100 mL.

In a preferred embodiment, both the epoxy compounds (b1) and the latent crosslinker (b2) are soluble in the reactive diluent (a1).

The amount of the latent crosslinker (b2) generally depends on the amount of epoxy compound (b1). Usually, the amount of the latent crosslinker (b2) can be in the range from 2 to 30 wt. %, for example 5 wt. %, 10 wt. %, 15 wt. %, 20 wt. %, 25 wt. %, preferably from 10 to 30 wt. % or from 10 to 25 wt. % or from 10 to 20 wt. %, based on the total weight of the curable composition.

The total amount of component (b) can be in the range from 7 to 79 wt. %, for example 8 wt. %, 9 wt. %, 10 wt. %, 15 wt. %, 20 wt. %, 30 wt. %, 40 wt. %, 50 wt. %, 60 wt. %, or 70 wt. %, preferably from 7 to 69 wt. %, or 9 to 59 wt. %, more preferably from 20 to 59 wt. %, or from 30 to 55 wt. %.

The weight ratio of component (a) to component (b) can be in the range from 1:5 to 20:1, for example 1:4, 1:3, 1:2, 1:1, 2:1, 5:1, 10:1, 15:1, preferably from 1:3 to 10:1 or from 1:3 to 5:1, from 1:2 to 10:1 or from 1:2 to 5:1, from 1:1.5 to 10:1 or from 1:1.5 to 5:1, from 1:1.1 to 10:1 or from 1:1.1 to 5:1.

### Photoinitiator (C)

The curable composition comprises at least one photoinitiator as component (C). For example, the photoinitiator component (C) may include at least one free radical photoinitiator and/or at least one ionic photoinitiator, and preferably at least one (for example one or two) free radical photoinitiator. For example, it is possible to use all photoinitiators known in the art for use in compositions for 3D-printing, e.g., it is possible to use photoinitiators that are known in the art use with SLA, DLP or PPJ (Photo polymer jetting) processes.

Exemplary photoinitiators may include benzophenone, acetophenone, chlorinated acetophenone, dialkoxyacetophenones, dialkylhydroxyacetophenones, dialkylhydroxyacetophenone esters, benzoin and derivative (such as benzoin acetate, benzoin alkyl ethers), dimethoxybenzion, dibenzylketone, benzoylcyclohexanol and other aromatic ketones, alpha-aminoketone compounds, phenylglyoxylate compounds, oxime ester, acyloxime esters, acylphosphine oxides, acylphosphonates, ketosulfides, dibenzoyldisulphides, diphenyldithiocarbonate, mixtures thereof and mixtures with alpha-hydroxy ketone compounds, or alpha-alkoxyketone compounds. Examples of suitable acylphosphine oxide compounds are of the formula (XII),

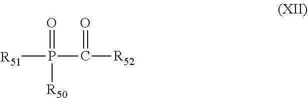

wherein
R₅₀ is unsubstituted cyclohexyl, cyclopentyl, phenyl, naphthyl or biphenylyl; or is cyclohexyl, cyclopentyl, phenyl, naphthyl or biphenylyl substituted by one or more halogen, C₁-C₁₂ alkyl, C₁-C₁₂ alkoxy, C₁-C₁₂ alkylthio or by NR₅₃R₅₄;
or R₅₀ is unsubstituted C₁-C₂₀ alkyl or is C₁-C₂₀ alkyl which is substituted by one or more halogen, C₁-C₁₂ alkoxy, C₁-C₁₂ alkylthio, NR₅₃R₅₄ or by —(CO)—O—C₁-C₂₄ alkyl;
R₅₁ is unsubstituted cyclohexyl, cyclopentyl, phenyl, naphthyl or biphenylyl; or is cyclohexyl, cyclopentyl, phenyl, naphthyl or biphenylyl substituted by one or more halogen, C₁-C₁₂ alkyl, C₁-C₁₂ alkoxy, C₁-C₁₂ alkylthio or by NR₅₃R₅₄; or R₅₁ is —(CO)R′₅₂; or R₅— is C₁-C₁₂ alkyl which is unsubstituted or substituted by one or more halogen, C₁-C₁₂ alkoxy, C₁-C₁₂ alkylthio, or by NR₅₃R₅₄;
R₅₂ and R′₅₂ independently of each other are unsubstituted cyclohexyl, cyclopentyl, phenyl, naphthyl or biphenylyl, or are cyclohexyl, cyclopentyl, phenyl, naphthyl or biphenylyl substituted by one or more halogen, C₁-C₄ alkyl or C₁-C₄ alkoxy; or R₅₂ is a 5- or 6-membered heterocyclic ring comprising an S atom or N atom;
R₅₃ and R₅₄ independently of one another are hydrogen, unsubstituted C₁-C₁₂ alkyl or C₁-C₁₂ alkyl substituted by one or more OH or SH wherein the alkyl chain optionally is interrupted by one to four oxygen atoms; or R₅₃ and R₅₄ independently of one another are C₂-C₁₂ alkenyl, cyclopentyl, cyclohexyl, benzyl or phenyl.

Specific examples of photoinitiators can include 1-hydroxycyclohexyl phenylketone, 2-methyl-1-[4-(methylthio)phenyl]-2-morpholinopropan-1-one, 2-benzyl-2-N,N-dimethylamino-1-(4-morpholinophenyl)-1-butanone, combination of 1-hydroxycyclohexyl phenyl ketone and benzophenone, 2,2-dimethoxy-2-phenyl acetophenone, bis(2,6-dimethoxybenzoy 1-(2,4,4-trimethylpentyl)phosphine oxide, 2-hydroxy-2-methyl-1-phenyl-propan-1-one, bis(2,4,6-trimethyl benzoyl) phenyl phosphine oxide, 2-hydroxy-2-methyl-1-phenyl-1-propane, combination of 2,4,6-trimethylbenzoyldiphenyl-phosphine oxide, 2-hydroxy-2-methyl-1-phenyl-propan-1-one, 2,4,6-trimethylbenzoyldiphenylphosphinate and 2,4,6-trimethylbenzoyldiphenyl-phosphine oxide and also any combination thereof.

In a particularly preferred embodiment, the photoinitiator (C) is a compound of the formula (XII), such as, for example, bis(2,4,6-trimethylbenzoyl)-phenylphosphine oxide; 2,4,6-trimethylbenzyldiphenyl-phosphine oxide; ethyl (2,4,6-trimethylbenzoyl phenyl) phosphinic acid ester; (2,4,6-trimethylbenzoyl)-2,4-dipentoxyphenylphosphine oxide and bis(2,6-dimethoxybenzoyl)-2,4,4-trimethylpentylphosphine oxide.

The amount of the photoinitiator (C) can be in the range from 0.1 to 10 wt. %, for example 0.2 wt. %, 0.5 wt. %, 0.8 wt. %, 1 wt. %, 2 wt. %, 3 wt. %, 5 wt. %, 8 wt. %, or 10 wt. %, preferably from 0.1 to 5 wt. % or 0.5 to 5 wt. % or from 0.5 to 3 wt. %, based on the total weight of the composition.

In one embodiment, the curable composition of the present invention, comprising following components:
(a) 20 to 94 wt. % at least one light polymerizable liquid;
(b) 5 to 79 wt. % at least one epoxy precursor; and
(c) 0.1 to 10 wt. % at least one photoinitiator;
based on the total weight of the curable composition.

In one embodiment, the curable composition of the present invention, comprising following components:
(a) 30 to 92 wt. % at least one light polymerizable liquid;
(b) 7 to 69 wt. % at least one epoxy precursor; and
(c) 0.1 to 10 wt. % at least one photoinitiator;
based on the total weight of the curable composition.

In one embodiment, the curable composition of the present invention, comprising following components:
(a) 40 to 90 wt. % at least one light polymerizable liquid;
(b) 9 to 59 wt. % at least one epoxy precursor; and
(c) 0.1 to 10 wt. % at least one photoinitiator;
based on the total weight of the curable composition.

In one embodiment, the curable composition of the present invention, comprising following components:
(a) 40 to 75 wt. % at least one light polymerizable liquid;
(b) 20 to 59 wt. % at least one epoxy precursor; and
(c) 0.1 to 5 wt. % at least one photoinitiator;
based on the total weight of the curable composition.

In one embodiment, the curable composition of the present invention, comprising following components:
(a) 40 to 75 wt. % at least one light polymerizable liquid;
(b) 20 to 59 wt. % at least one epoxy precursor; and
(c) 0.5 to 5 wt. % at least one photoinitiator;
based on the total weight of the curable composition.

In a preferred embodiment, the curable composition of the present invention, comprising following components:
(a1) 10 to 50 wt. % at least one mono-functional reactive diluent;
(a2) 10 to 60 wt. % at least one photopolymerizable compound containing at least one ethylenically unsaturated functional group;
(b1) 5 to 50 wt. % at least one epoxy compound;
(b2) 2 to 30 wt. % at least one latent epoxy crosslinker; and
(c) 0.1 to 10 wt. % at least one photoinitiator;
based on the total weight of the curable composition.

In a preferred embodiment, the curable composition of the present invention, comprising following components:
(a1) 15 to 50 wt. % at least one mono-functional reactive diluent;
(a2) 10 to 55 wt. % at least one photopolymerizable compound containing at least one ethylenically unsaturated functional group;
(b1) 10 to 50 wt. % at least one epoxy compound;
(b2) 10 to 30 wt. % at least one latent epoxy crosslinker; and
(c) 0.1 to 10 wt. % at least one photoinitiator;
based on the total weight of the curable composition.

In a preferred embodiment, the curable composition of the present invention, comprising following components:
(a1) 10 to 40 wt. % at least one mono-functional reactive diluent;
(a2) 15 to 50 wt. % at least one photopolymerizable compound containing at least one ethylenically unsaturated functional group;
(b1) 15 to 50 wt. % at least one epoxy compound;
(b2) 10 to 25 wt. % at least one latent epoxy crosslinker; and
(c) 0.1 to 10 wt. % at least one photoinitiator;
based on the total weight of the curable composition.

In a preferred embodiment, the curable composition of the present invention, comprising following components:
(a1) 10 to 40 wt. % at least one mono-functional reactive diluent;
(a2) 15 to 50 wt. % at least one photopolymerizable compound containing at least one ethylenically unsaturated functional group;
(b1) 15 to 50 wt. % at least one epoxy compound;
(b2) 10 to 25 wt. % at least one latent epoxy crosslinker; and
(c) 0.5 to 5 wt. % at least one photoinitiator;
based on the total weight of the curable composition.

### Impact Modifier (D)

The curable composition of the present invention can optionally comprise at least one impact modifier (D).

In an embodiment, the impact modifier can be selected from acrylic rubbers, ASA rubbers, diene rubbers, organosiloxane rubbers, EPDM rubbers, SBS or SEBS rubbers, ABS rubbers, MBS rubbers, glycidyl esters, polystyrene-polybutadiene, polystyrene-poly(ethylene-propylene), polystyrene-polyisoprene, poly(α-methylstyrene)-polybutadiene, polystyrene-polybutadiene-polystyrene, polystyrene-poly(ethylene-propylene)-polystyrene, polystyrene-polyisoprene-polystyrene, poly(α-methylstyrene)-polybutadiene-poly(α-methylstyrene), methylmethacrylate-butadiene-styrene (MBS) and methylmethacrylate-butylacrylate, polyalkylacrylates grafted with polymethylmethacrylate, polyalkylacrylates grafted with styrene-acrylonitrile co-polymer, poly-olefins grafted with poly ethylmethacrylate, polyolefins grafted with styrene-acrylonitrile co-polymer, butadiene core-shell polymers, polyphenylene ether-polyamide, polyamides, styrene-acrylonitrile co-polymer, styrene-acrylonitrile co-polymer grafted onto polybutadiene, or a combination of any two or more.

In an embodiment, the impact modifier comprises a first component and a second component, wherein the first component is a co-polymer of ethylene and an unsaturated epoxides, and the second component is a co-polymer of ethylene and an alkyl (meth)acrylate. The unsaturated epoxide is typically selected from allyl glycidyl ether, vinyl glycidyl ether, glycidyl maleate and itaconate, glycidyl (meth)acrylate, 2-cyclohexene-1-glycidyl ether, cyclohexene-4,5-diglycidyl carboxylate, cyclohexane-4-glycidyl carboxylate, 5-norbornene-2-methyl-2-glycidyl carboxylate, or endo-cis-bicyclo-(2,2,1)-5-heptene-2,3-diglycidyl dicarboxylate. The alkyl (meth)acrylate is typically selected from methyl (meth)acrylate, ethyl acrylate, n-butyl acrylate, isobutyl acrylate, n-octyl acrylate, or 2-ethylhexyl acrylate.

In one embodiment, useful impact modifiers are substantially amorphous copolymer resins, including but not limited to acrylic rubbers, ASA rubbers, diene rubbers, organosiloxane rubbers, EPDM rubbers, SBS or SEBS rubbers, ABS rubbers, MBS rubbers and glycidyl ester impact modifiers.

Acrylic rubbers are multi-stage, core-shell, interpolymer compositions having a cross-linked or partially cross linked (meth)acrylate rubbery core phase, preferably butyl acrylate. Associated with this cross-linked acrylic ester core is an outer shell of an acrylic or styrenic resin, preferably methyl methacrylate or styrene, which interpenetrates the rubbery core phase. Incorporation of small amounts of other monomers such as acrylonitrile or (meth)acrylonitrile within the resin shell also provides suitable impact modifiers. The interpenetrating network is provided when the monomers forming the resin phase are polymerized and cross-linked in the presence of the previously polymerized and cross-linked (meth)acrylate rubbery phase. Specific example includes core shell acrylic polymer particles consisting of a crosslinked polybutyl acrylate core and a polymethylmethacrylate shell prepared by emulsion polymerization and isolated via spray drying (PARALOID EXL 2300G from the Dow Chemical Co.).

In another embodiment, block co-polymers and rubbery impact modifiers are provided. For example, A-B-A triblock co-polymers and A-B diblock co-polymers. The A-B and A-B-A type block co-polymer rubber additives which may be used as impact modifiers include thermoplastic rubbers comprised of one or two alkenyl aromatic blocks which are typically styrene blocks and a rubber block, e.g., a butadiene block which may be partially hydrogenated. Mixtures of these triblock co-polymers and diblock co-polymers are especially useful.

Suitable A-B and A-B-A type block co-polymers are disclosed in, for example, U.S. Pat. Nos. 3,078,254; 3,402,159; 3,297,793; 3,265,765; and 3,594,452 and U.K. Patent 1,264,741. Examples of typical species of A-B and A-B-A block co-polymers include polystyrene-polybutadiene (SBR), polystyrene-poly(ethylene-propylene), polystyrene-polyisoprene, poly(α-methylstyrene)-polybutadiene, polystyrene-polybutadiene-polystyrene (SBR), polystyrene-poly(ethylene-propylene)-polystyrene, polystyrene-polyisoprene-polystyrene and poly(α-methylstyrene)-polybutadiene-poly(α-methylstyrene), as well as the selectively hydrogenated versions thereof, and the like. Mixtures comprising at least one of the aforementioned block co-polymers are also useful. Such A-B and A-B-A block co-polymers are available commercially from a number of sources, including Phillips Petroleum under the trademark SOLPRENE, Shell Chemical Co., under the trademark KRATON, Dexco under the trade name VECTOR, and Kuraray under the trademark SEPTON.

Other rubbers useful as impact modifiers include graft and/or core shell structures having a rubbery component with a Tg (glass transition temperature) below 0° C., preferably between about −40° C. to about −80° C., which comprise polyalkylacrylates or polyolefins grafted with polymethyl-methacrylate or styrene-acrylonitrile co-polymer. The rubber content is at least about 40 wt. % in some embodiments, at least about 60 wt. % in other embodiments, and from about 60 wt. % to about 90 wt. %, in yet other embodiments.

Other suitable rubbers for use as impact modifiers are the butadiene core-shell polymers of the type available from Rohm & Haas under the trade name P ARALO ID® EXL2600. Most preferably, the impact modifier will comprise a two-stage polymer having a butadiene based rubbery core, and a second stage polymerized from methylmethacrylate alone or in combination with styrene. Impact modifiers of the type also include those that comprise acrylonitrile and styrene grafted onto cross-linked butadiene polymer, which are disclosed in U.S. Pat. No. 4,292,233.

Other impact modifiers useful herein include those which comprise polyphenylene ether, a polyamide or a combination of polyphenylene ether and a polyamide. The composition may also comprise a vinyl aromatic-vinyl cyanide co-polymer. Suitable vinyl cyanide compounds include acrylonitrile and substituted vinyl cyanides such a methacrylonitrile. Preferably the impact modifier comprises styrene-acrylonitrile co-polymer (hereinafter SAN). The preferred SAN composition comprises at least 10 wt. % acrylonitrile (AN), in some embodiments, and from about 25 wt. % to about 28 wt. % AN, in other embodiments, with the remainder styrene, p-methyl styrene, or alpha methyl styrene. Another example of SANs useful herein include those modified by grafting SAN to a rubbery substrate such as, for example, 1,4-polybutadiene, to produce a rubber graft polymeric impact modifier. High rubber content (greater than 50 wt %) resin of this type (HRG-ABS) may be especially useful for impact modification of polyester resins and their polycarbonate blends.

In some embodiments, the impact modifier is a high rubber graft ABS modifier, comprise greater than or equal to 90 wt. % SAN grafted onto polybutadiene, the remainder being free SAN. Some exemplary embodiments include compositions of about 8 wt. % acrylonitrile, 43 wt. % butadiene and 49 wt. % styrene, and about 7 wt. % acrylonitrile, 50 wt. % butadiene and 43 wt. % styrene. These materials are commercially available under the trade names BLENDEX 336 and BLENDEX 415 respectively (G.E. Plastics, Pittsfield, Mass.).

Other suitable impact modifiers may be mixtures comprising core shell impact modifiers made via emulsion polymerization using alkyl acrylate, styrene and butadiene. These include, for example, methylmethacrylate-butadiene-styrene (MBS) and methylmethacrylate-butylacrylate core shell rubbers.

Other suitable impact modifiers include those having at least a first component that is a co-polymer of ethylene and an unsaturated epoxide that can be obtained by co-polymerization of ethylene and an unsaturated epoxide, or by grafting the unsaturated epoxide onto polyethylene, and at least a second component that is a co-polymer of ethylene and an alkyl (meth)acrylate.

The first component is typically a co-polymer of ethylene and an unsaturated epoxide that can be obtained by co-polymerization of ethylene and an unsaturated epoxide, or by grafting the unsaturated epoxide onto polyethylene. Such grafting may be carried out in the solvent phase, or on molten polyethylene, in the presence of a peroxide. Co-polymerization of ethylene and an unsaturated epoxide may be carried out by as free-radical polymerization methods. The free-radical polymerization may be performed at pressures from about 200 bar to about 2500 bar.

Unsaturated epoxides that are suitable for use in the first component include, but are not limited to, aliphatic glycidyl esters and ethers such as allyl glycidyl ether, vinyl glycidyl ether, glycidyl maleate and itaconate, glycidyl (meth)acrylate; and alicyclic esters and ethers such as 2-cyclohexene-I-glycidyl ether, cyclohexene-4,5-diglycidyl carboxylate, cyclohexane-4-glycidyl carboxylate, 5-norbornene-2-methyl-2-glycidyl carboxylate and endo-cis-bicyclo-(2,2,1)-5-heptene-2,3-diglycidyl dicarboxylate. In some embodiments, the epoxide is glycidyl (meth)acrylate.

Other monomers that may be incorporated into the first component include, but are not limited to, α-olefins such as propylene, 1-butene, and hexane; vinyl esters of saturated carboxylic acids such as vinyl acetate or vinyl propionate; and esters of saturated carboxylic acids such as alkyl (meth)acrylates having from 2 to 24 carbon atoms.

In grafting unsaturated epoxides to other polymers, suitable other polymers include, but are not limited to, polyethylene (PE); co-polymers of ethylene and an alpha-olefin; co-polymers of ethylene and at least one vinyl ester of a saturated carboxylic acid, such as vinyl acetate or vinyl propionate; co-polymers of ethylene and at least one ester of an unsaturated carboxylic acid, such as an alkyl (meth)acrylate with an alkyl group having from 2 to 24 carbon atoms; ethylene/propylene rubber (EPR) elastomers; ethylene/propylene/diene (EPDM) elastomers; and mixtures of any two or more such polymers. For example, materials such as VLDPE (PE of very low density), ULDPE (PE of ultra-low density), or PE metallocene polymers, may be used. As used herein, PE metallocene polymers are polyethylene polymers produced with metallocene catalysts such as early transition metal metallocenes. Titanocene dichloride and zirconocene dichloride are but two such examples known to those of skill in the art.

In some embodiments, the first component is an ethylene/alkyl(meth)acrylate/unsaturated epoxide co-polymer containing up to 40 wt. % of alkyl (meth)acrylate.

Suitable the alkyl (meth)acrylate for use in the impact modifiers include, but are not limited to those of having from 2 to 24 carbon atoms. For example, methyl (meth)acrylate, ethyl acrylate, n-butyl acrylate, isobutyl acrylate, n-octyl acrylate and 2-ethylhexyl acrylate, are several that may be used. The quantity of alkyl (meth)acrylate may range from about 20 wt. % to about 35 wt. %.

As noted, carboxylic acid anhydride functionality may be incorporated into the first component. Suitable examples of the co-polymers of ethylene, an alkyl (meth)acrylate, and an anhydride of an unsaturated carboxylic acid and co-polymers of ethylene, a vinyl ester of a saturated carboxylic acid and an anhydride of an unsaturated carboxylic acid. In some embodiments the anhydride functionality is the anhydride of an unsaturated dicarboxylic acid. For example, maleic anhydride, itaconic anhydride, citraconic anhydride and tetrahydrophthalic anhydride are some examples. The quantity of unsaturated carboxylic anhydride can be up to 15 wt. % of the co-polymer, and the quantity of ethylene at least 50 wt. %.

In some embodiments, the fluidity index (MFI), of the first component is from about 0.1 to about 50 g/10 min at 190° C. under 2.16 kg; from about 2 to about 40 g/10 min at 190° C. under 2.16 kg, in other embodiments; and from about 5 to about 20 g/10 min at 190° C. under 2.16 kg, in yet other embodiments.

The second component is typically a co-polymer of ethylene and an alkyl(meth)acrylate. Suitable alkyl (meth)acrylates include those as described above, including, but not limited to, ethyl acrylate, n-butyl acrylate, isobutyl acrylate, n-octyl acrylate and 2-ethylhexyl acrylate. The quantity of alkyl (meth)acrylate in the second component ranges from about 20 wt. % to about 40 wt. %.

In forming the impact modifier, the wt. % ratio of the first component in the mixture ranges from about 10 wt. % to about 50 wt. %, in some embodiments, from about 15 wt. % to about 40 wt. %, in some other embodiments, and from about 20 wt. % to about 30 wt. %, in some further embodiments. Impact modifiers that are rich in ethylene-alkyl (meth)acrylate co-polymer show improved impact resistance at room temperature and lower. Such impact resistance is higher than that of compositions which are rich in ethylene-alkyl (meth)acrylate-glycidyl acrylate co-polymer.

The impact modifier in the curable composition of the present invention could be present in an amount of from 0 to 15 wt. %, for example from 1 to 15 wt. %, more preferably from 3 to 12 wt. %, based on the total weight of the curable composition.

### Auxiliaries (E)

The composition of the present invention may further comprise one or more auxiliaries.

As auxiliaries, mention may be made by way of preferred example of surface-active substances, flame retardants, nucleating agents, lubricant wax, dyes, pigments, catalyst, UV absorbers and stabilizers, e.g. against oxidation, hydrolysis, light, heat or discoloration, inorganic and/or organic fillers, reinforcing materials and plasticizers. As hydrolysis inhibitors, preference is given to oligomeric and/or polymeric aliphatic or aromatic carbodiimides. To stabilize the material cured of the invention against aging and damaging environmental influences, stabilizers are added to system in preferred embodiments.

If the composition of the invention is exposed to thermo-oxidative damage during use, in preferred embodiments antioxidants are added. Preference is given to phenolic antioxidants. Phenolic antioxidants such as Irganox® 1010 from BASF SE are given in Plastics Additive Handbook, 5th edition, H. Zweifel, ed., Hanser Publishers, Munich, 2001, pages 98-107, page 116 and page 121.

If the composition of the invention is exposed to UV light, it is preferably additionally stabilized with a UV absorber. UV absorbers are generally known as molecules which absorb high-energy UV light and dissipate energy. Customary UV absorbers which are employed in industry belong, for example, to the group of cinnamic esters, diphenylcyan acrylates, formamidines, benzylidenemalonates, diarylbutadienes, triazines and benzotriazoles. Examples of commercial UV absorbers may be found in Plastics Additive Handbook, 5th edition, H. Zweifel, ed, Hanser Publishers, Munich, 2001, pages 116-122.

Further details regarding the abovementioned auxiliaries may be found in the specialist literature, e.g. in Plastics Additive Handbook, 5th edition, H. Zweifel, ed, Hanser Publishers, Munich, 2001.

According to the present invention, the auxiliary can be present in an amount of from 0 to 50% by weight, from 0.01 to 50% by weight, for example from 0.5 to 30% by weight, based on the total weight of the curable composition.

### Preparation of the Composition

A further aspect of this disclosure relates to a process of preparing the curable composition of the present invention, comprising mixing the components of the composition.

According to an embodiment of the invention, the mixing can be carried out at room temperature or preferably at an elevated temperature (for example from 30 to 90° C., preferably from 35 to 80° C.) with stirring. There is no particular restriction on the time of mixing and rate of stirring, as long as all components are uniformly mixed together. In a specific embodiment, the mixing can be carried out at 1000 to 3000 RPM, preferably 1500 to 2500 RPM for 5 to 60 min, more preferably 6 to 30 min.

### Coating and Preparation Thereof

One aspect of the present disclosure relates to a process of coating, comprising using the curable composition of the present invention or the curable composition obtained by the process of the present invention.

In an embodiment, the process of coating comprises
(i) apply a layer of the composition onto the surface of a structure;
(ii) applying light to cure the curable composition according to the present invention to form an intermediate coating;
(iii) treating the cured coating by heating and/or microwave irradiating to form a final coating.

In a specific embodiment, the wavelength of the radiation light can be in the range from 350 to 420 nm, for example 355, 360, 365, 385, 395, 405, 420 nm. The energy of radiation can be in the range from 0.5 to 2000 mw/cm², for example 1 mw/cm², 2 mw/cm², 3 mw/cm², 4 mw/cm², 5 mw/cm², 8 mw/cm², 10 mw/cm², 20 mw/cm², 30 mw/cm², 40 mw/cm², or 50 mw/cm², 100 mw/cm², 200 mw/cm², 400 mw/cm², 500 mw/cm², 1000 mw/cm², 1500 mw/cm² or 2000 mw/cm², preferably 200 to 2000 mw/cm². The radiation time can be in the range from 0.5 to 10 s, preferably from 0.6 to 6 s.

Usually, the temperature in the thermal treatment in step (iii) is in the range from 130 to 220° C., preferably 150 to 200° C. According to the invention, the treating time in step (iii) can be in the range from 30 min to 500 min, for example 60 min, 120 min, 180 min, 250 min, 300 min, 400 min, preferably from 60 min to 250 min.

### 2D Object and Preparation Thereof

One aspect of the present disclosure relates to a process of forming 2D object, comprising using the curable composition of the present invention or the curable composition obtained by the process of the present invention.

In an embodiment, the process of forming 2D object comprises
(i) dispensing composition onto a substrate to form designed patterns;
(ii) applying light to cure the curable composition according to the present invention to form an intermediate 2D object;
(iii) treating the cured 2D object as a whole by heating and/or microwave irradiating to form a final 2D object.

In a specific embodiment, the wavelength of the radiation light can be in the range from 350 to 420 nm, for example 355, 360, 365, 385, 395, 405, 420 nm. The energy of radiation can be in the range from 0.5 to 2000 mw/cm². The radiation time can be in the range from 0.5 to 10 s, preferably from 0.6 to 6 s.

The process of forming 2D objects can include inkjet printing, photolithography, and other technique known by the skilled in the art.

Preferably, the production of cured 2D objects of complex shape is performed for instance by inkjet printing, which has been known for a number of years. In this technique, the desired shaped article is built from a radiation-curable composition with the aid of an ink dispensing device, alternating sequence of two steps (1) and (2). In step (1), a layer of the radiation-curable composition is dispensed to the desired positions on a substrate, during which the movement of ink dispensing device is controlled by computer; And in step (2), radiation is applied to the dispensed composition to form a 2D object.

The production of cured 2D objects of complex shape can also be performed for instance by means of photolithography. In this technique, the desired shaped article is formed from a radiation-curable composition with the aid of appropriate imaging radiation, preferably imaging radiation from a computer-controlled scanning laser beam, within a surface region which corresponds to the desired cross-sectional area of the shaped article to be formed.

Usually, the temperature in the thermal treatment in step (iii) is in the range from 130 to 220° C., preferably 150 to 200° C. According to the invention, the treating time in step (iii) can be in the range from 30 min to 500 min, for example 60 min, 120 min, 180 min, 250 min, 300 min, 400 min, preferably from 60 min to 250 min.

### 3D-Printed Object and Preparation Thereof

One aspect of the present disclosure relates to a process of forming 3D-printed object, comprising using the curable composition of the present invention or the curable composition obtained by the process of the present invention.

In an embodiment, the process of forming 3D object comprises
(i) applying light to cure the curable composition according to the present invention layer by layer to form an intermediate 3D object;
(ii) further applying light to cure the intermediate 3D object as a whole to form a cured 3D object; and
(iii) treating the cured 3D object as a whole by heating and/or microwave irradiating to form a final 3D object.

In a specific embodiment, the wavelength of the radiation light can be in the range from 350 to 420 nm, for example 355, 360, 365, 385, 395, 405, 420 nm. The energy of radiation can be in the range from 0.5 to 2000 mw/cm², for example 1 mw/cm², 2 mw/cm², 3 mw/cm², 4 mw/cm², 5 mw/cm², 8 mw/cm², 10 mw/cm², 20 mw/cm², 30 mw/cm², 40 mw/cm², or 50 mw/cm², 100 mw/cm², 200 mw/cm², 400 mw/cm², 500 mw/cm², 1000 mw/cm², 1500 mw/cm² or 2000 mw/cm², preferably from 0.5 to 50 mw/cm² for digital light processing or from 0.5 to 400 mw/cm² for stereolithography or from 0.5 to 2000 mw/cm² for photopolymer jetting. The radiation time can be in the range from 0.5 to 10 s, preferably from 0.6 to 6 s.

The process of forming 3D-printed objects can include stereolithography (SLA), digital light processing (DLP) or photopolymer jetting (PPJ) and other technique known by the skilled in the art. Preferably, the production of cured 3D objects of complex shape is performed for instance by means of stereolithography, which has been known for a number of years. In this technique, the desired shaped article is built up from a radiation-curable composition with the aid of a recurring, alternating sequence of two steps (1) and (2). In step (1), a layer of the radiation-curable composition, one boundary of which is the surface of the composition, is cured with the aid of appropriate imaging radiation, preferably imaging radiation from a computer-controlled scanning laser beam, within a surface region which corresponds to the desired cross-sectional area of the shaped article to be formed, and in step (2) the cured layer is covered with a new layer of the radiation-curable composition, and the sequence of steps (1) and (2) is often repeated until the desired shape is finished.

Usually, the temperature in the thermal treatment in step (iii) is in the range from 130 to 220° C., preferably 150 to 200° C. According to the invention, the treating time in step (iii) can be in the range from 30 min to 500 min, for example 60 min, 120 min, 180 min, 250 min, 300 min, 400 min, preferably from 60 min to 250 min.

A further aspect of the present disclosure relates to a 3D-printed object formed from the curable composition of the present invention or obtained by the process of the present invention.

The 3D-printed objects can include plumbing fixtures, household, toy, jig, mould and interior part and connector within a vehicle.

The 3D-printed objects of the present invention can have a HDT at 1.82 MPa of more than 100° C., preferably more than 115° C., more preferably more than 125° C. and/or a HDT at 0.455 MPa of more than 120° C., preferably more than 130° C., more preferably more than 140° C., in particularly more than 145° C.

### EXAMPLES

The present invention is further illustrated by the following examples, which are set forth to illustrate the present invention and is not to be construed as limiting thereof. Unless otherwise noted, all parts and percentages are by weight.

### Materials and Abbreviation

Component (a):
Miramer PE210: bifunctional epoxy acrylate, weight average molecular weight 520, manufactured by MIWON;
Miramer M240: ethylene oxide (average 4 mol) modified bisphenol A diacrylate (BisA-EO4-DA), manufactured by MIWON, monomer viscosity at 25° C., 1100 millipascal seconds, weight average molecular weight 512, manufactured by MIWON;
Bomar BRC-843D: bifunctional urethane acrylate, Tg 45° C., viscosity 4200 cP at 60° C., manufactured by Dymax;
Sartomer SR833S: tricyclodecane dimethanol diacrylate, available from Sartomer Co., Exton, PA;
DPGDA: Dipropylene Glycol Diacrylate;
VMOX: Vinyl methyl oxazolidinone; wherein the solubility of DDS in VMOX is more than 60%;
NVP: N-vinylpyrrolidone; wherein the solubility of DDS in NVP is more than 40%;
NVCL: N-vinyl caprolactam; wherein the solubility of DDS in NVCL is more than 50%.

Component (b):
DGEBA: Bisphenol A diglycidyl ether; Araldite MY 790-1, difunctional bisphenol A based epoxy resin. Molecular weight: 338-352 g/mol, Epoxy value: 5.7-5.9 eq./kg, manufactured by Huntsman;
DDS: 4,4′-Diamino Diphenyl Sulfone; Solid; Mp 175° C.;
MTHPA: Methyltetrahydrophthalic anhydride; liquid;
MHHPA: Methyl hexhydrophthalic anhydride; liquid;
MNA: Methyl Nadic anhydride; liquid.

Component (c):
TPO: 2,4,6-trimethylbenzoyldiphenylphosphine oxide from Omnicure.

Component (d):
PARALOID EXL 2300G: Core shell acrylic polymer particles consisting of a crosslinked polybutyl acrylate core and a polymethylmethacrylate shell prepared by emulsion polymerization and isolated via spray drying (the Dow Chemical Co.);
Albidur® EP 2240A: a dispersion of a high-performance elastomer in an epoxy resin based on bisphenol A with a silicone rubber content of 40 wt. % and an EEW of 290-315 g/eq (Evonik).

### Methods

### (1) Tensile Test

Tensile tests were carried out according to ISO 527-5A:2009 with Zwick, Z050 Tensile equipment, wherein the parameters used include: Start position: 50 mm; Pre-load: 0.02 MPa; Test speed: 50 mm/min.

### (2) Viscosity

Viscosities were measured using a Brookfield AMETEK DV3T rheometer. For each test, approximately 0.65 ml of sample was used, and shear rates between 1 s⁻¹ and 30 s⁻¹ were selected according to the viscosities.

### (3) Izod Notched Impact Strength (ASTM-D256-10)

### (4) Izod Unnotched Impact Strength (ASTM-D4812-11)

### (5) Heat Deflection Temperature (HDT) (ASTM-D648-07)

### Example 1—Storage Stability of DGEBA/DDS in VMOX

Epoxy compound DGEBA was mixed with latent epoxy crosslinkers DDS (pre-dissolved in VMOX). The amount of each component and viscosity of DGEBA/DDS/VMOX mixture (EP1) after storage at room temperature were shown in table 1 below.

TABLE 1
viscosity of DGEBA/DDS/VMOX mixture

| | EP1 |
|---|---|
| DGEBA (g) | 100 |
| DDS (g) | 40 |
| VMOX (g) | 420 |
| Viscosity at 25° C. (mPa · s) − 0 h | 43.5 |

### Examples 2 and 3

The curable compositions in examples 2 and 3 were prepared by adding all components in amounts as shown in table 2 into a plastic vial and mixing by speed-mixer at 2000 RPM for 10 minutes at 50° C. to obtain the liquid curable compositions.

The curable compositions were prepared into test specimens using UV casting method, during which the curable compositions were poured into a pre-defined Teflon/silicone mould followed by UV irradiation. UV-curing of the curable compositions was done using an JSCC convey curer, which equips with 2 Firefly LED lamps (385 nm and 405 nm). For consistency, the UV dose applied was determined based on the thickness of the sample. For ISO527A tensile test specimen with a thickness of 2 mm, each sample was cured using a convey speed of 3 m/min for 4 times, 2 times for each side. For ASTM D256A impact strength test specimen with a thickness of 3 mm, the samples were cured for 6 times in total. Then, thermal treatment was performed by heating samples at 150° C. for 1 hour followed by 200° C. for 3 hours.

The physical properties of the cured samples obtained from compositions of examples 2 and 3 via casting were also shown in table 2.

TABLE 2

| Ingredients | Example 2 | Example 3 |
|---|---|---|
| DGEBA (g) | 7.1 | 36.1 |
| DDS (g) | 2.7 | 14 |
| VMOX (g) | 39.8 | 22 |
| 843D (g) | 48.6 | 26.9 |
| TPO (g) | 1.8 | 1 |
| Tensile modulus (MPa) | 597 | 1550 |
| Tensile strength (MPa) | 27.8 | 28 |
| Elongation at break (%) | 58.4 | 3.5 |
| Izod notched impact strength (J/m) | 263.3 | 11.0 |

### Example 4 and Comparative Example 1

The curable compositions in example 4 was prepared by adding all components in amounts as shown in table 3 into a plastic vial and mixing by speed-mixer at 2000 RPM for 10 minutes at 50° C. to obtain the liquid curable compositions.

TABLE 3

| Components | Weight parts |
|---|---|
| DGEBA | 36 |
| DDS | 14 |
| VMOX | 25 |
| PE210 | 12.5 |
| DPGDA | 12.5 |
| 2300G | 5 |
| Omnicure TPO | 2 |

The curable composition of examples 4 was printed using a MiiCraft 150 3D printer, which is a desktop Digital Light Processing (DLP) 3D printer with light wavelength at 405 nm. For a typical printing process, curable compositions were loaded into a vat within the printer. Detailed printing parameters are summarized as follows: UV energy 4.75 mW/cm², base curing time 6.0 s, base layer 1, curing time 2.0 s, buffer layer 5.

After a 3D printing process, the printed parts were soaked in ethanol and shook for 10 seconds to remove uncured resin on the surface, followed by being dried using compressed air. Parts with smooth-dry surfaces can be obtained after being UV post-cured for 40 minutes using a NextDent post-curing unit (LC-3DPrint box). Thermal treatment was performed by heating samples at 150° C. for 1 hour followed by 200° C. for 3 hours.

The physical properties of the cured samples obtained from composition of example 4 via 3D-printing were shown in table 4. The composition of comparative example 1 was a commercial product Carbon-EPX81 (2K resin) from Carbon and the physical properties of this commercial product were also shown in table 4.

TABLE 4

| | | Comparative |
|---|---|---|
| | | example 1 |
| Properties | Example 4 | (Carbon-EPX81) |
| Viscosity @ 25° C. (mPa · s) | 947.3 | N/A |
| Tensile modulus (MPa) | 3120 | 3140* |
| Tensile strength (MPa) | 86.4 | 88* |
| Elongation at break (%) | 4.4 | 5.2* |
| Izod notched impact strength (J/m) | 28 | 23 |
| Izod unnotched impact strength (J/m) | 510 | 291 |
| HDT@1.82 MPa (° C.) | 130 | 131 |
| HDT@0.455 MPa (° C.) | 150 | 140 |

*Tested according to ASTM-D638(5)

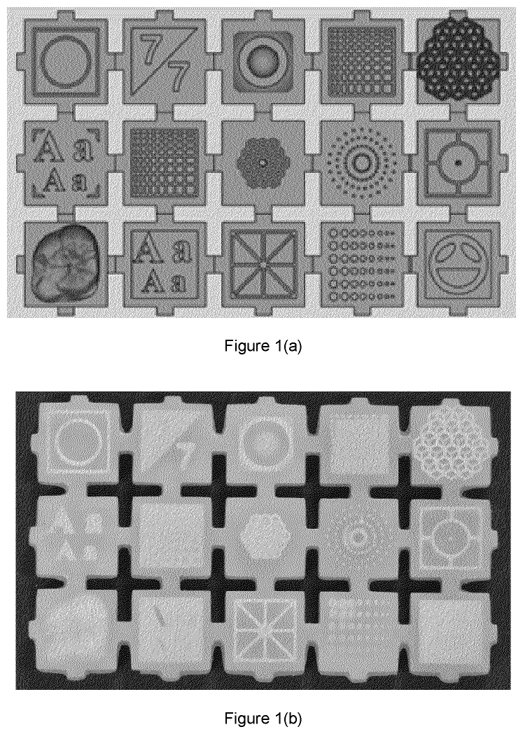

The picture of 3D-printed object obtained by printing the composition of example 4 according to the standard benchmark model was shown in FIG. 1(b). The comparison between the standard benchmark model (FIG. 1(a)) and FIG. 1(b) demonstrated that good printing accuracy could be achieved by the curable composition of the present invention.

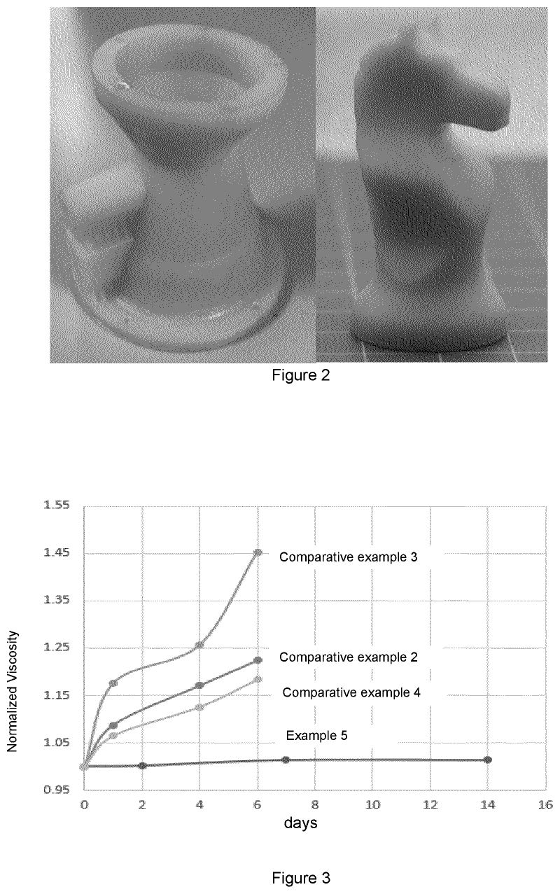

The pictures of 3D-printed objects obtained by printing the composition of example 4 were shown in FIG. 2.

### Example 5 and Comparative Examples 2, 3 and 4

The curable compositions of example 5 and comparative examples 2, 3 and 4 were prepared by adding all components in amounts as shown in table 5 into a plastic vial and mixing by speed-mixer at 2000 RPM for 10 minutes at 50° C. to obtain the liquid curable compositions. The viscosities of each composition after storage at room temperature for different days were also shown in Table 5. The normalized viscosities of compositions of example 5 and comparative examples 2, 3 and 4 after storage at room temperature for different days were shown in FIG. 3.

TABLE 5

| | | Comparative | Comparative | Comparative |
|---|---|---|---|---|
| Components | Example 5 | example 2 | example 3 | example 4 |
| Sartomer SR833S | 25 | 25 | 25 | 25 |
| (g) | | | | |
| Miramer M240 | 25 | 25 | 25 | 25 |
| (g) | | | | |
| VMOX (g) | 50 | 50 | 50 | 50 |
| TPO (g) | 4 | 4 | 4 | 4 |
| DGEBA (g) | 72.26 | 72.26 | 72.26 | 72.26 |
| MTHPA (g) | | 28 | | |
| MHHPA (g) | | | 28 | |
| MNA (g) | | | | 28 |
| DDS (g) | 28 | | | |
| Paraloid EXL | 10 | 10 | 10 | 10 |
| 2300G (g) | | | | |

| | viscos- | viscos- | viscos- | viscos- |
|---|---|---|---|---|
| | ity@25° C. | ity@25° C. | ity@25° C. | ity@25° C. |
| Stored Days | (mPa · s) | (mPa · s) | (mPa · s) | (mPa · s) |
| 0 | 994.8 | 233 | 255.5 | 284.1 |
| 1 | | 253.4 | 300.4 | 302.5 |
| 2 | 996.3 | | | |
| 4 | | 272.8 | 320.9 | 319.8 |
| 5 | | | | |
| 6 | | 285.1 | 370.9 | 336.2 |
| 7 | 1009 | | | |
| 14 | 1009 | | | |

As could be seen, the viscosity of the composition of example 5 was only slightly increased after 7 days and there was no change in viscosity from 7 to 14 days. The compositions of comparative examples 2, 3 and 4 showed more than 18% increase in viscosity only after 7 days.

### Examples 6, 7 and 8

The curable compositions in examples 6, 7 and 8 were prepared by adding all components in amounts as shown in table 6 into a plastic vial and mixing by speed-mixer at 2000 RPM for 10 minutes at 50° C. to obtain the liquid curable compositions. The physical properties of the samples obtained from these compositions via casting were also shown in table 6. The casting method was the same as casting method described in examples 2 and 3 (comprising both UV-curing and thermal treatment).

TABLE 6

| Formulation | Example 6 | Example 7 | Example 8 |
|---|---|---|---|
| SR833S | 25 | 25 | 25 |
| M240 | 25 | 25 | 25 |
| VMOX | 50 | | |
| NVCL | | 50 | |
| NVP | | | 50 |
| TPO | 4 | 4 | 4 |
| DGEBA | 72.26 | 72.26 | 72.26 |
| DDS | 28 | 28 | 28 |
| Paraloid EXL 2300G | 10 | 10 | 10 |
| E-Modulus (MPa) | 3650 | 3110 | 3310 |
| ISO 527-5A | | | |
| Tensile strength (Mpa) | 85.5 | 80.3 | 89.3 |
| Elongation (%) | 4.28 | 3.75 | 5.28 |
| ISO 527-5A | | | |
| Impact strength (J/m) | 14.61 | 22.3 | 19.53 |
| ASTM D256 | | | |
| unnothced Impact | 360.55 | 396.65 | 378.24 |
| strength (J/m) | | | |
| ASTM D4812 | | | |
| Viscosity | 994.8 | 1453 | 467.5 |
| (mPa · s @ 25° C.) | | | |

The viscosity of the composition of example 6 was lower than that of the composition of example 7, which means the printability of the composition of example 6 was better than that of the composition of example 7.

1.-19. (canceled)

20. A curable composition comprising
(a) at least one light polymerizable liquid;
(b) at least one epoxy precursor dissolved in component (a); and
(c) at least one photoinitiator;
wherein the curable composition exhibits no more than 15% increase in viscosity at 25° C. after 7 days at room temperature.

21. The curable composition according to claim 20, wherein the curable composition exhibits no more than 10% increase in viscosity at 25° C. after 7 days at room temperature.

22. The curable composition according to claim 20, wherein component (a) comprises at least one mono-functional reactive diluent (a1) having a nitrogen atom carrying an ethylenically unsaturated functional group.

23. The curable composition according to claim 22, wherein the reactive diluent (a1) is a N-vinyl heterocyclic compound.

24. The curable composition according to claim 23, wherein the heterocyclic ring of the N-vinyl heterocyclic compound is a 5- to 8-membered ring containing 0 to 3 heteroatoms selected from the group consisting of N, O and S in addition to the nitrogen atom in the N-vinyl moiety.

25. The curable composition according to claim 22, wherein the reactive diluent (a1) is selected from the group consisting of N-vinylpyrrolidone, N-vinyl caprolactam and N-vinyl oxazolidinone of formula (A): 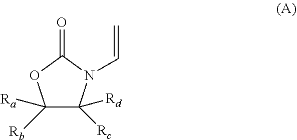
wherein Rₐ, R_{b}, R_{c} and R_{d} are independently of each other a hydrogen atom or an organic group having not more than 10 carbon atoms.

26. The curable composition according to claim 22, wherein the amount of the reactive diluent (a1) is in the range from 10 to 50 wt. % based on the total weight of the curable composition.

27. The curable composition according to claim 22, wherein component (a) further comprises at least one photopolymerizable compound (a2) containing at least one ethylenically unsaturated functional group.

28. The curable composition according to claim 20, wherein the amount of component (a) is in the range from 20 to 94 wt. % based on the total weight of the curable composition.

29. The curable composition according to claim 20, wherein the epoxy precursor as component (b) comprises reactive end groups selected from the group consisting of epoxy/amine, epoxy/hydroxyl, and mixtures thereof.

30. The curable composition according to claim 20, wherein the epoxy precursor as component (b) comprises at least one epoxy compound (b1) and at least one latent epoxy crosslinker (b2).

31. The curable composition according to claim 30, wherein the melting point of the latent epoxy crosslinker (b2) is in the range from 100 to 250° C.

32. The curable composition according to claim 30, wherein the latent epoxy crosslinker is diamino diphenyl sulfone and/or derivative thereof.

33. The curable composition according to claim 30, wherein the latent epoxy crosslinker is selected from the group consisting of the compound of formula (I), compound of formula (II) and compound of formula (III): 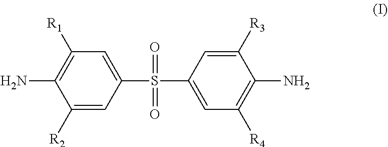
wherein R₁, R₂, R₃ and R₄ are each independently H or C₁-C₆ alkyl; 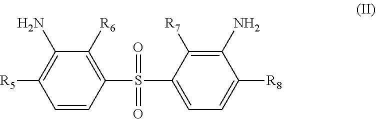
wherein R₅, R₆, R₇ and R₈ are each independently H or C₁-C₆ alkyl; 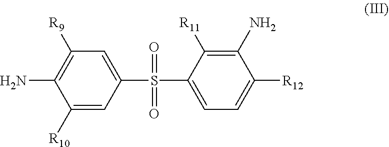
wherein R_{9,} R₁₀, R₁₁ and R₁₂ are each independently H or C₁-C₆ alkyl.

34. The curable composition according to claim 20, wherein weight ratio of component (a) to component (b) is in the range from 1:5 to 20:1.

35. A process of forming single layer coating or 2D object, comprising
(i) applying a layer of the curable composition according to claim 20 onto a surface of a structure;
(ii) applying light to cure the curable composition to form an intermediate coating or 2D object;
(iii) treating the cured coating or 2D object as a whole by heating and/or microwave irradiating to form a final coating or 2D object.

36. A process of forming 3D object, comprising
(i) applying light to cure the curable composition according to claim 20 layer by layer to form an intermediate 3D object;
(ii) further applying light to cure the intermediate 3D object as a whole to form a cured 3D object; and
(iii) treating the cured 3D object as a whole by heating and/or microwave irradiating to form a final 3D object.

37. A single layer coating or 2D object or 3D object formed from the curable composition according to claim 20.

38. The 3D object according to claim 37, wherein the 3D object is selected from the group consisting of plumbing fixtures, household, toy, jig, mould and interior part and connector within a vehicle.
